(19) United States
(12) Patent Application Publication
(10) Pub. No.: US 2021/0035795 A1
(43) Pub. Date: Feb. 4, 2021

(54) METHODS AND APPARATUS FOR SUBSTRATE WARPAGE CORRECTION

(71) Applicant: APPLIED MATERIALS, INC., Santa Clara, CA (US)

(72) Inventors: Qi Jie PENG, Singapore (SG); Prayudi LIANTO, Singapore (SG); Chin Wei TAN, Singapore (SG); Sriskantharajah THIRUNAVUKARASU, Singapore (SG); Arvind SUNDARRAJAN, Singapore (SG); Jun-Liang SU, Singapore (SG); Fang Jie LIM, Singapore (SG); Manorajh ARUNAKIRI, Singapore (SG); Wei Jie Dickson TEO, Singapore (SG); Karrthik PARATHITHASAN, Singapore (SG); Puay Han TAN, Singapore (SG)

(21) Appl. No.: 16/936,918

(22) Filed: Jul. 23, 2020

Related U.S. Application Data
(60) Provisional application No. 62/880,247, filed on Jul. 30, 2019.

(51) Int. Cl. H01L 21/02; H01L 21/683; H01L 21/324

(52) U.S. Cl. CPC H01L 21/02035; H01L 21/3247; H01L 21/6831

(57) ABSTRACT

Methods and apparatus for reducing warpage of a substrate. In some embodiments, a method of reducing substrate warpage comprises heating the substrate with an epoxy layer to at least a glass transition temperature of the epoxy layer while allowing the substrate to expand; maintaining the at least the glass transition temperature of the substrate until the substrate is constrained; constraining the substrate with a total clamping force of approximately 5000N to approximately 7000N exerted towards the substrate from a top direction and a bottom direction; applying at least one electrostatic field to the substrate with a first electrostatic chuck positioned above the substrate and a second electrostatic chuck positioned below the substrate; and rapidly cooling the substrate using a first liquid convection heat sink positioned above the substrate and a second liquid convection heat sink positioned below the substrate.

### CROSS-REFERENCE TO RELATED APPLICATIONS

This application claims benefit of U.S. provisional patent application Ser. No. 62/880,247, filed Jul. 30, 2019 which is herein incorporated by reference in its entirety.

### FIELD

Embodiments of the present principles generally relate to semiconductor processing.

### BACKGROUND

Warped substrates are a problem which prevents the substrates from being chucked fully on a process station pedestal. Such warpage leads to a delay in or ceasing of the substrate processing. For example, epoxy mold compounds are used to encapsulate dies in substrate packaging. These compounds bow and warp after thermal processes due to inhomogeneous heating and cooling, causing non-uniform expansion/contraction rates in current process equipment. Conventional thermal processes utilize directional heat transfer that results in anisotropic expansion and contraction rates. When operated near the thermoplastic regime, non-uniform cooling and, subsequently, contraction rates give rise to a warped substrate. Such warp and bow effects are frequently observed and imply that the substrate is being processed close to the thermoplastic regime of the substrate, giving rise to substrate warpage beyond acceptable levels. Being able to reduce warpage found in substrates would allow otherwise unusable substrates to be used, dramatically increasing production yields.

### SUMMARY

Methods and apparatus for reducing warpage of a substrate used in semiconductor processes are provided herein.

In some embodiments, a method of method for reducing warpage of a substrate may comprise heating the substrate with an epoxy layer to at least a glass transition temperature of the epoxy layer while allowing the substrate to expand, constraining the substrate with a clamping force exerted towards the substrate from a top direction and a bottom direction, applying at least one electrostatic field to the substrate, and rapidly cooling the substrate.

In some embodiments, the method may further include maintaining the at least the glass transition temperature of the substrate until the substrate is constrained, constraining the substrate with a clamping force of approximately 5000N to approximately 7000N, generating the electrostatic field with a first electrostatic chuck positioned above the substrate and a second electrostatic chuck positioned below the substrate, using at least one liquid convection heat sink to rapidly quench cool the substrate at a rate of approximately 1300 W/m²° C. to approximately 3100 W/m²° C. to retain an elongated and low stress state of the epoxy layer, using a first liquid convection heat sink positioned above the substrate and a second liquid convection heat sink positioned below the substrate, generating at least one electrostatic field with at least one electrostatic chuck with two embedded half-moon electrodes, heating the substrate to a glass transition temperature of approximately 100 degrees Celsius to approximately 200 degrees Celsius, applying at least one electrostatic field with a positive or negative voltage of approximately 500 volts to approximately 2000 volts, heating the substrate with a gas at a temperature of approximately 200 degrees Celsius to approximately 300 degrees Celsius and a pressure of approximately 1 bar to approximately 2 bar, and/or concurrently constraining the substrate, cooling the substrate, and applying the electrostatic field to the substrate for approximately 30 seconds to approximately 300 seconds.

In some embodiments, a non-transitory, computer readable medium having instructions stored thereon that, when executed, cause a method of reducing warpage of a substrate to be performed where the method may include heating the substrate with an epoxy layer to at least a glass transition temperature of the epoxy layer while allowing the substrate to expand, maintaining the at least the glass transition temperature of the substrate until the substrate is constrained, constraining the substrate with a total clamping force of approximately 5000N to approximately 7000N exerted towards the substrate from a top direction and a bottom direction, applying at least one electrostatic field to the substrate with a first electrostatic chuck positioned above the substrate and a second electrostatic chuck positioned below the substrate, and rapidly cooling the substrate using a first liquid convection heat sink positioned above the substrate and a second liquid convection heat sink positioned below the substrate.

In some embodiments, the method on the non-transitory, computer readable medium may further include heating the substrate to a glass transition temperature of approximately 100 degrees Celsius to approximately 200 degrees Celsius, applying at least one electrostatic field with a voltage of approximately 500 volts to approximately 2000 volts, and/or concurrently constraining the substrate, cooling the substrate, and applying the electrostatic field to the substrate for approximately 30 seconds to approximately 300 seconds.

In some embodiments, an apparatus for reducing warpage of a substrate with an epoxy layer may include a first station with a gas heating system and a transferable pedestal that holds the substrate, wherein the first station is configured to heat the substrate to at least a glass transition temperature of the epoxy layer; and a second station with a first warpage control assembly configured to receive the substrate from the first station, to provide a clamping force to a bottom surface of the substrate, to provide an electrostatic field to the substrate, and to provide cooling to the substrate, and a second warpage control assembly located above the first warpage control assembly configured to provide a clamping force to a top surface of the substrate, to provide an electrostatic field to the substrate, and to provide cooling to the substrate, wherein the first station and the second station are configured to transfer the substrate between the first station and the second station with the transferable pedestal while maintaining the at least the glass transition temperature of the substrate.

In some embodiments, that apparatus may further include wherein the first warpage control assembly has a lift pin assembly for raising and lowering the substrate on and off of an upper surface of the first warpage control assembly, the first station further comprising a gas distribution assembly located at a top of the first station; and a conduction heater assembly positioned under the transferable pedestal, wherein the first station is configured to heat the substrate with a heated gas supplied by the gas distribution assembly from above the substrate and to heat the substrate with the conduction heater assembly from below the substrate; infrared heat detectors located at a bottom of the first station and configured to detect a temperature of a bottom surface of the substrate, wherein the transferable pedestal has openings that permit direct readings from the bottom surface of the substrate by the infrared heat detectors; and/or the second station further comprising an annular gas distribution assembly is positioned at a top of the second station and outward of the second warpage control assembly, wherein the annular gas distribution assembly is configured to surround the substrate with heated gas to maintain the at least the glass transition temperature of the substrate; a first liquid convection cooling assembly configured to rapidly cool a bottom surface of the substrate, wherein the first liquid convection cooling assembly is formed of aluminum material with vacuum brazed cooling channels; a second liquid convection cooling assembly configured to rapidly cool a top surface of the substrate concurrently with the first liquid convection cooling assembly, wherein the second liquid convection cooling assembly is formed of aluminum material with vacuum brazed cooling channels; a first electrostatic chuck assembly configured to apply a first electrostatic field of approximately 500 volts to approximately 2000 volts below the substrate, wherein the first electrostatic chuck assembly is formed of aluminum nitride material with at least two electrodes configured to provide the first electrostatic field; and a second electrostatic chuck assembly configured to apply a second electrostatic field of approximately 500 volts to approximately 2000 volts above the substrate concurrently with the first electrostatic chuck assembly, wherein the second electrostatic chuck assembly is formed of aluminum nitride material with at least two electrodes configured to provide the second electrostatic field, wherein the first liquid convection cooling assembly is affixed to a lower surface of the first electrostatic chuck assembly with a first thermal transfer tape with a transfer conductivity of approximately 0.5 W/mK and approximately 1.0 W/mK, wherein the second liquid convection cooling assembly is affixed to an upper surface of the second electrostatic chuck assembly with a second thermal transfer tape with a transfer conductivity of approximately 0.5 W/mK and approximately 1.0 W/mK, and wherein the first warpage control assembly is configured to be raised and lowered and to provide a clamping force to the substrate by raising the substrate until the substrate is clamped between the first warpage control assembly and the second warpage control assembly.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of reducing warpage in a substrate in accordance with some embodiments of the present principles.

FIG. 2 is a cross-sectional view of a substrate that may be processed in accordance with some embodiments of the present principles.

FIG. 3 is an illustration of forces applied to a substrate during heating and cooling which may be circumvented in accordance with some embodiments of the present principles.

FIG. 4 is a cross-sectional view of a substrate having a warp reduced in accordance with some embodiments of the present principles.

FIG. 5 is another method of reducing warpage in a substrate in accordance with some embodiments of the present principles.

FIG. 6 is a cross-sectional view of an apparatus for reducing warpage of a substrate in accordance with some embodiments of the present principles.

FIG. 7 is a top down view of an apparatus for reducing warpage of a substrate in accordance with some embodiments of the present principles.

FIGS. 8A-8D illustrate a method of reducing warpage of a substrate in accordance with some embodiments of the present principles.

FIG. 9 is a cross-sectional view of a lower warpage control assembly in accordance with some embodiments of the present principles.

FIG. 10 is a cross-sectional view of an upper warpage control assembly in accordance with some embodiments of the present principles.

FIG. 11 is an illustration of epoxy filler migration in accordance with some embodiments of the present principles.

FIG. 12 is a top down view of an electrostatic chuck in accordance with some embodiments of the present principles.

FIG. 13 is a bottom view of an annular gas delivery assembly in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus reduce warpage of substrates to allow subsequent semiconductor processing. When a substrate has warpage greater than 2 mm, the substrate is generally deemed unusable. Even backgrinding processes require less than 2 mm in warpage in order to be utilized. In semiconductor back end of the line (BEOL) packaging, 2.5D is a methodology for including multiple die inside the same package. The 2.5D approach is used for applications where performance and low power are critical. In a 2.5D wafer, communication between chips is established using either a silicon or organic interposer, typically a chip or layer with through-silicon vias (TSV) for communication. 2.5D architectures have been paired with stacked memory modules, such as High-Bandwidth Memory (HBM), to further improve performance. High warpage of 2.5D wafers is a pressing industrial problem as the warpage prevents the 2.5D wafers from flowing on to downstream processes. Wafer handling challenges and reduction in yield are the most common detrimental effects of high 2.5D wafer warpage. The methods and apparatus of the present principles may be applied to correct warpage of a 2.5D wafer which is fully encapsulated with epoxy mold compound or to correct warpage of any multilayer substrates. The methods and apparatus reduce warpage using only two thermal treatments, saving time and possible damage to delicate circuits, especially those sensitive to thermal budgets and smaller structures that are more easily damaged by thermal changes.

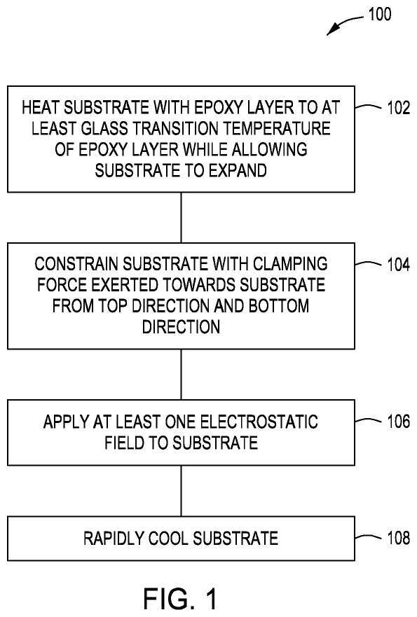

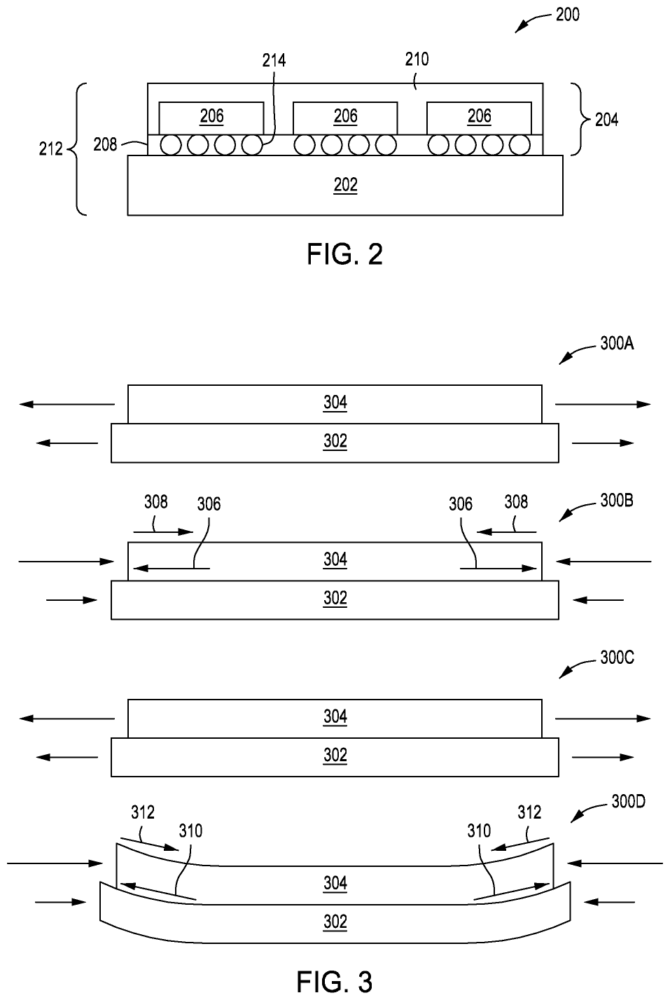

FIG. 1 is a method 100 of reducing warpage of a substrate 212 as illustrated in FIG. 2 and in accordance with some embodiments. FIG. 2 is a cross-sectional view 200 of the substrate 212. In some embodiments, the substrate 212 may include an interposer layer 202 with an epoxy mold encapsulation layer 204. The epoxy mold encapsulation layer 204 may include epoxy mold 210, embedded chips 206, and an epoxy mold under fill layer 208. The epoxy mold under fill layer 208 may also include solder bumps 214. In block 102, the substrate 212 is heated to a temperature that is at least a glass transition temperature of the epoxy material used in the epoxy mold encapsulation layer 204 while allowing the substrate 212 to freely expand. The epoxy material may vary and, subsequently, the glass transition temperature will also vary. In addition, some epoxy materials utilize fillers in the epoxy material which also may influence heating to the glass transition temperature. In block 104, the substrate 212 is constrained with a clamping force that is exerted towards the substrate from a top direction and from a bottom direction. In block 106, at least one electrostatic field is applied to the substrate 212 to help reduce migration of the fillers in the epoxy material. In block 108, the substrate 212 is rapidly cooled to lock in the constrained shape of the substrate 212. The constraining of the substrate 212, the application of the electric field to the substrate 212, and the rapid cooling of the substrate 212 are accomplished approximately concurrently. In some embodiments, the concurrent constraining of the substrate, cooling of the substrate, and applying the electrostatic field to the substrate occurs for approximately 30 seconds to approximately 300 seconds.

FIG. 3 is an illustration of forces applied to a substrate during heating and cooling which may be mitigated in accordance with some embodiments. In view 300A, the substrate is being heated. An interposer layer 302 expands during heating but with a coefficient of thermal expansion (CTE) of less than half the CTE of an epoxy mold encapsulation layer 304. In view 300B, the substrate is being cooled causing thermal contraction. Because of the differences in CTE, the epoxy mold encapsulation layer 304 contracts more than the interposer layer 302. Tensile stress forces 306 result at the union of the epoxy mold encapsulation layer 304 and the interposer layer 302 because of the differences in CTE. The differences in CTE also cause compressive stress forces 308 to form at an upper portion of the epoxy mold encapsulation layer 304. In view 300C, the substrate is cured causing differences in thermal expansion and shrinkage of the epoxy material in the epoxy mold encapsulation layer 304 along with polymerization. The curing establishes the mechanical properties of E.M.C. (Elastic Modulus, CTE α1 and CTE α2). In view 300D, thermal contraction occurs with different forces on each layer when the substrate is cooled after curing. The cured epoxy contraction in the epoxy mold encapsulation layer 304 is restricted by the silicon in the interposer layer 302 during post cure cooling. A higher elasticity modulus of the epoxy material exerts higher stress forces on the silicon. High tensile stress forces 310 form at the bonding interface between the epoxy mold encapsulation layer 304 and the interpose layer 302. High compressive stress forces 312 form at an upper portion of the epoxy mold encapsulation layer 304 which causes both layers to warp after post cure cooling.

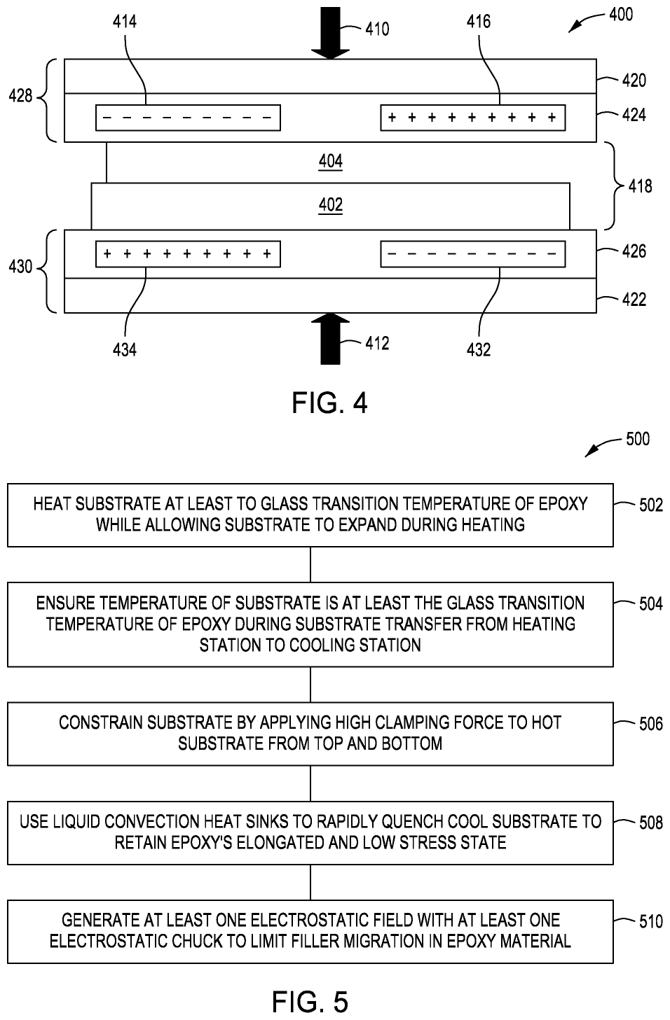

In FIG. 4, a cross-sectional view 400 of a substrate 418 with an interposer layer 402 and an epoxy mold encapsulation layer 404 is having a warp reduced in accordance with some embodiments. The substrate 418 is clamped between an upper warpage control assembly 428 and a lower warpage control assembly 430. The upper warpage control assembly 428 provides a downward clamping force 410 towards the substrate 418. The lower warpage control assembly 430 provides an upward clamping force 412 towards the substrate 418. The upper warpage control assembly 428 includes an upper cooling assembly 420 and an upper electrostatic chuck assembly 424. In some embodiments, the upper cooling assembly 420 may include liquid convection heat sinks for rapidly cooling the substrate. The transfer fluid (liquid) may be water or other coolants. The lower warpage control assembly 430 includes a lower cooling assembly 422 and a lower electrostatic chuck assembly 426. In some embodiments, the lower cooling assembly 422 may include liquid convection heat sinks for rapidly cooling the substrate. The transfer fluid (liquid) may be water or other coolants. As described above in method 100, the substrate 418 is heated to at least a glass transition temperature of the epoxy material used in the epoxy mold encapsulation layer 404 prior to the clamping forces 410, 412 being applied. The upper electrostatic chuck assembly 424 includes an upper negative charge electrode 414 and an upper positive charge electrode 416 to induce an upper electric field into the substrate 418. The lower electrostatic chuck assembly 426 includes a lower negative charge electrode 432 and a lower positive charge electrode 434 to induce a lower electric field into the substrate 418.

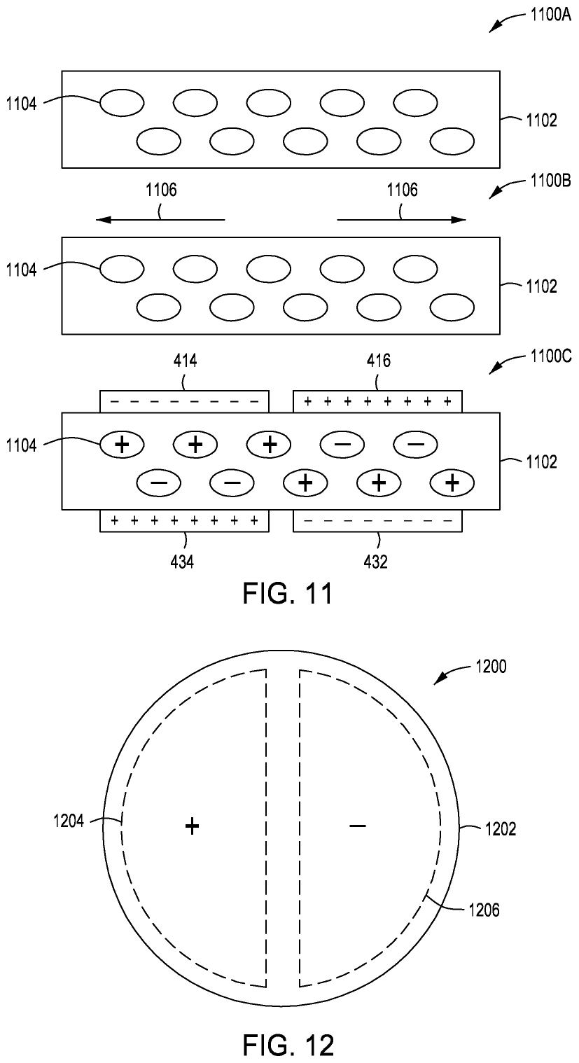

In FIG. 12, a top down view 1200 of an electrostatic chuck 1202 in accordance with some embodiments is shown. The electrostatic chuck 1202 has a positive electrode 1204 and a negative electrode 1206 embedded within the electrostatic chuck and configured to induce an electric field or electrostatic charge into a substrate. In some embodiments, the negative electrode 1206 may have a negative voltage of approximately 500 volts to approximately 2000 volts. In some embodiments, the negative electrode 1206 may have a negative voltage of approximately 1000 volts. In some embodiments, the positive electrode 1204 may have a positive voltage of approximately 500 volts to approximately 2000 volts. In some embodiments, the positive electrode 1204 may have a positive voltage of approximately 1000 volts. In some embodiments, the positive electrode 1204 and the negative electrode 1206 may have a half moon shape as illustrated in FIG. 12. In some embodiments, the electrostatic chuck 1202 may have multiple pairs of electrodes with varying shapes and coverage within the electrostatic chuck 1202. The upper and lower electric fields are applied while the substrate 418 is being constrained to retard migration of fillers in the epoxy material. FIG. 11 is an illustration of epoxy filler migration in accordance with some embodiments. In view 1100A, an epoxy layer 1102 includes fillers 1104 that are dispersed throughout the epoxy. As shown in view 1100B, when the epoxy layer 1102 is heated, the fillers 1104 migrate outward 1106. As shown in view 1100C, by applying an upper electric field with the upper negative charge electrode 414 and the upper positive charge electrode 416 and by applying a lower electric field with the lower negative charge electrode 432 and the lower positive charge electrode 434, the fillers 1104 are attracted to opposite charges and are prevented from migrating outward as shown in view 1100B.

FIG. 5 is another method 500 of reducing warpage in a substrate in accordance with some embodiments. The substrate includes an interposer layer and an epoxy encapsulation layer. In block 502, the substrate is heated to at least a glass transition temperature of the epoxy material used in the epoxy encapsulation layer. In some embodiments, the glass transition temperature of the epoxy material may be from approximately 140 degrees Celsius to approximately 180 degrees Celsius. In some embodiments, the glass transition temperature of the epoxy material may be from approximately 100 degrees Celsius to approximately 200 degrees Celsius. In block 504, the temperature of the substrate is maintained to at least the glass transition temperature of the epoxy material during transfer of the substrate from a heating station to a cooling station. In some embodiments, the temperature may be maintained by using a transferable pedestal (described in detail below) with conduction heating for transferring the substrate between heating and cooling stations. In some embodiments, the temperature may also be maintained by using heated gas dispersed around the substrate (described in detail below) while the substrate is being positioned within a cooling station and until the substrate has clamping forces applied to the substrate. In block 506, the substrate is transferred to the cooling station where the substrate is constrained by applying a high clamping force to the hot substrate from the top of the substrate and the bottom of the substrate. In some embodiments, the high clamping force may be from approximately 5000N (newtons) to approximately 7000N (newtons). In some embodiments the high clamping force may be approximately 5000N. In block 508, liquid convection heat sinks may be utilized to rapidly quench cool the substrate while the substrate is constrained to retain the epoxy's elongated and low stress state. The rapid quench cool may occur at a rate of approximately 1300 W/m²° C. to a rate of approximately 3100 W/m²° C. In block 510, at least one electrostatic field or electric field is generated with at least one electrostatic chuck to limit filler migration in the epoxy material. In some embodiments, the electric field is generated with a positive or negative voltage of approximately 500 volts to approximately 2000 volts. In some embodiments, the electric field is generated with a positive or negative voltage of approximately 1000 volts.

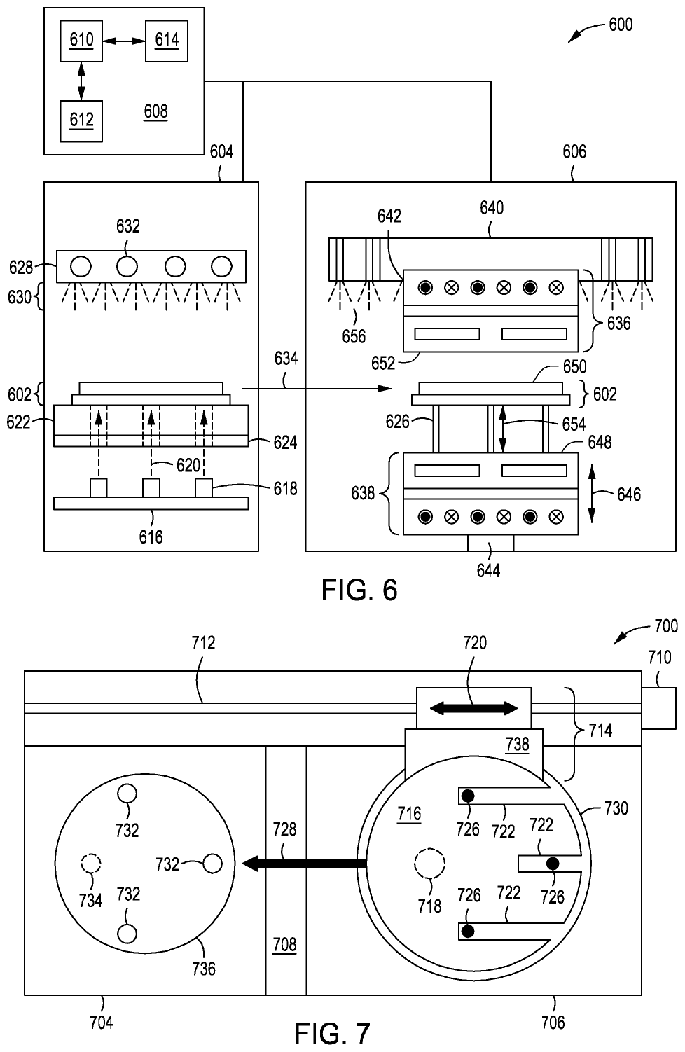

FIG. 6 is a cross-sectional view of an apparatus 600 for reducing warpage of a substrate 602 in accordance with some embodiments. The apparatus 600 includes a heating station 604, a cooling station 606, and a system controller 608. The system controller 608 controls the operation of the apparatus 600 using a direct control of the heating station 604 and the cooling station 606 or alternatively, by controlling the computers (or controllers) associated with the heating station 604 and the cooling station 606. In operation, the system controller 608 enables data collection and feedback from the respective stations and systems to optimize performance of the apparatus 600. The system controller 608 generally includes a Central Processing Unit (CPU) 610, a memory 612, and a support circuit 614. The CPU 610 may be any form of a general purpose computer processor that can be used in an industrial setting. The support circuit 614 is conventionally coupled to the CPU 610 and may comprise a cache, clock circuits, input/output subsystems, power supplies, and the like. Software routines, such as the methods described above may be stored in the memory 612 or other computer readable media and, when executed by the CPU 610, transform the CPU 610 into a specific purpose computer (system controller 608). The software routines may also be stored and/or executed by a second controller (not shown) that is located remotely from the apparatus 600.

In some embodiments, the heating station 604 may include a heat sensor assembly 616 that includes at least one heat sensor 618 that is configured to read 620 a bottom surface of the substrate 602. In some embodiments, the heat sensor 618 may be an infrared heat sensor and the like. The heat sensor 618 may be in communication with the system controller 608 to provide feedback on the heating of the substrate 602. The substrate 602 is supported by a transferable pedestal 622 that may include a convection heater 624 bonded to a lower surface of the transferable pedestal 622. The transferable pedestal 622 may be in communication with the system controller 608 to determine a position or status or the like of the transferable pedestal 622. Similarly, the convection heater 624 may be in communication with the system controller 608 so that the convection heater 624 can be configured to maintain at least a glass transition temperature of an epoxy material in the substrate 602. In some embodiments, the transferable pedestal 622 may have slots or holes through the transferable pedestal 622 to allow the heat sensor 618 to directly read the bottom surface of the substrate 602 and/or to allow the transferable pedestal to place the substrate 602 on lift pins 626 in the cooling station 606 (see FIG. 7 below).

The heating station 604 may also have a gas distribution assembly 628 above the transferable pedestal 622. The gas distribution assembly 628 provides heated gas 630 to heat the substrate 602 to at least the glass transition temperature of the epoxy material in the substrate 602. The heated gas may be heated by at least one infrared lamp 632 in the gas distribution assembly 628. In some embodiments, the gas distribution assembly 628 provides a gas at a temperature of approximately 200 degrees Celsius to approximately 300 degrees Celsius. In some embodiments, the gas distribution assembly 628 provides a gas at a temperature of approximately 240 degrees Celsius. In some embodiments, the gas distribution assembly 628 provides a gas at a pressure of approximately 1 bar to approximately 2.5 bar. In some embodiments, the gas distribution assembly 628 provides a gas at a pressure of approximately 1 bar to approximately 2 bar. In some embodiments, the gas may be nitrogen, nitrogen/air, and/or other inert gases. The gas distribution assembly 628 (including the at least one infrared lamp) may be in communication with the system controller 608 to configure the heating station 604 to heat the substrate 602 to the at least the glass transition temperature of the epoxy material in the substrate 602. The heating station 604 heats the substrate 602 to the at least the glass transition temperature of the epoxy material using the convection heater 624 of the transferable pedestal 622 and the gas distribution assembly 628. When the substrate 602 reaches at least the glass transition temperature of the epoxy material, the convection heater 624 of the transferable pedestal maintains the at least the glass transition temperature of the epoxy material as the transferable pedestal 622 moves with the substrate 602 into the cooling station 606 as indicated by the arrow 634.

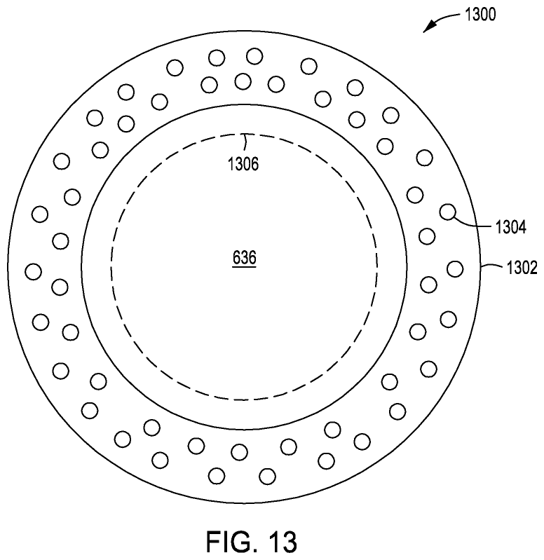

The cooling station 606 includes an upper warpage control assembly 636, a lower warpage control assembly 638, and a gas distribution assembly 640. The gas distribution assembly 640 is configured to provide hot gas into the cooling station 606 to facilitate in maintaining the at least the glass transition temperature of the epoxy material in the substrate 602 until the substrate 602 is constrained by the upper warpage control assembly 636 and the lower warpage control assembly 638. In some embodiments, the gas distribution assembly 628 provides a gas at a temperature of approximately 200 degrees Celsius to approximately 300 degrees Celsius. In some embodiments, the gas distribution assembly 640 provides a gas at a temperature of approximately 240 degrees Celsius. In some embodiments, the gas distribution assembly 640 provides a gas at a pressure of approximately 1 bar to approximately 2.5 bar. In some embodiments, the gas distribution assembly 640 provides a gas at a pressure of approximately 1 bar to approximately 2 bar. In some embodiments, the gas may be nitrogen, nitrogen/air, and/or other inert gases. In some embodiments, the gas distribution assembly 640 is an annular gas distribution assembly 1302 as illustrated in FIG. 13 which shows a bottom view of the annular gas distribution assembly 1302. The gas distribution assembly 640 or the annular gas distribution assembly 1302 includes at least one gas opening 1304 and is configured to project heated gas around the substrate 602 to maintain the temperature of the substrate 602. In FIG. 13, the annular gas distribution assembly 1302 provides a ring of heated gas in proximity of an outer periphery 1306 of the upper warpage control assembly 636. In some embodiments, as illustrated in FIG. 6, the gas distribution assembly 640 may encompass an upper portion 642 of the upper warpage control assembly 636.

In some embodiments, the lower warpage control assembly 638 may be affixed to an actuator 644 that is configured to move the lower warpage control assembly 638 in an upward and downward direction 646. In some embodiments, the upper warpage control assembly 636 may be held in a fixed position while the lower warpage control assembly 638 is moved upward by the actuator 644 when the substrate 602 is on an upper surface 648 of the lower warpage control assembly 638. As an upper surface 650 of the substrate 602 comes into contact with a lower surface 652 of the upper warpage control assembly 636, the actuator 644 continues to apply an upward force until a high clamping force is achieved (as described above). In some embodiments, the upper warpage control assembly 636 may be movable while the lower warpage control assembly 638 may remain in a fixed position to apply clamping forces to the substrate 602. In some embodiments, the upper warpage control assembly 636 may move downward and the lower warpage control assembly 638 may move upward to apply clamping forces to the substrate 602.

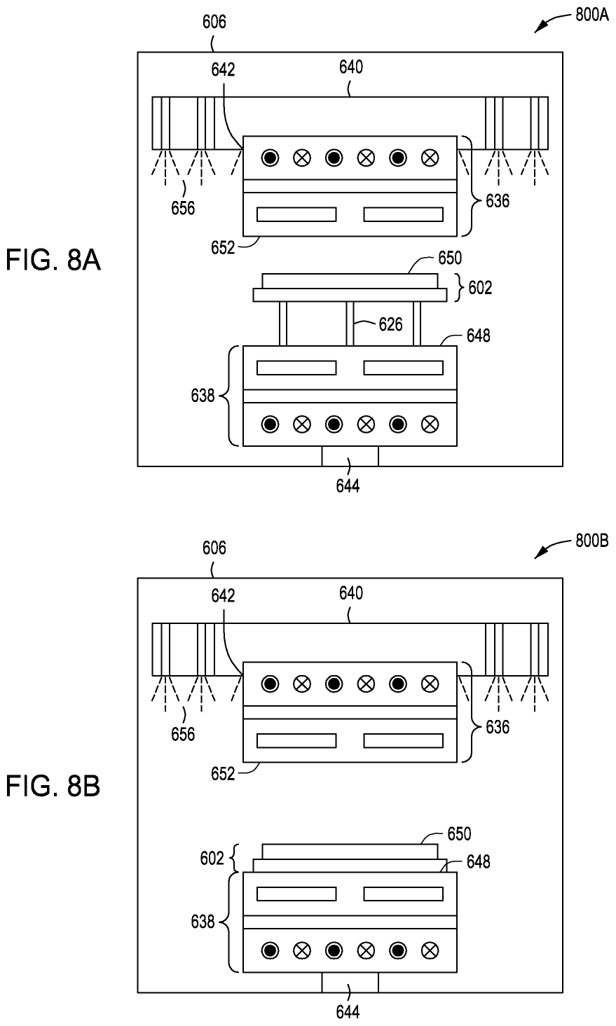

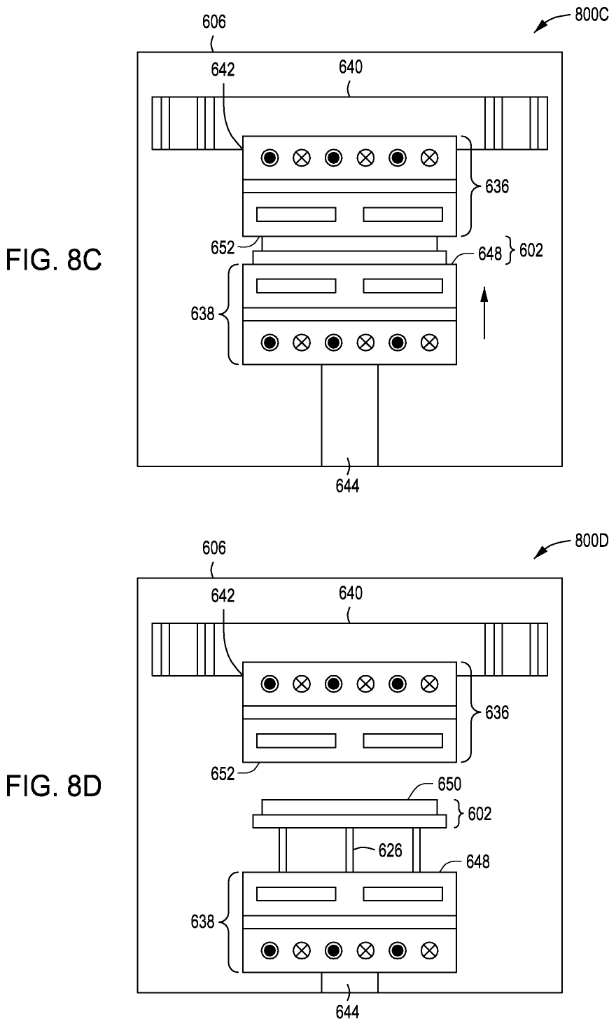

In some embodiments, the lower warpage control assembly 638 may also include a lift pin assembly with a plurality of lift pins 626 that are configured to raise and lower 654 the substrate 602 on and off of the upper surface 648 of the lower warpage control assembly 638. During processing, the lift pins 626 are in the raised position with hot gas 656 being projected from the gas distribution system 640 as the transferable pedestal 622 places the substrate 602 onto the lift pins 626. The transferable pedestal 622 continues to heat the substrate 602 with the convection heater 624 as the substrate 602 is moved from the heating station 604 to the cooling station 606. The transferable pedestal 622 places the substrate 602 onto the lift pins 626 and retreats back to the heating station 604 as illustrated in view 800A of FIG. 8A. The lift pins 626 are then lowered until the substrate 602 rests on the upper surface 648 of the lower warpage control assembly 638 while the hot gas 656 is continued to be projected around the substrate 602 to maintain the temperature of the substrate 602 as illustrate in view 800B of FIG. 8B. The substrate is then raised into position between the upper warpage control assembly 636 and the lower warpage control assembly 638 by the actuator 644. When clamping forces are applied by the actuator 644, the hot gas 656 stops and a cooling process begins as illustrated in view 800C of FIG. 8C. The upper warpage control assembly 636 and the lower warpage control assembly 638 are configured to create electric fields that are applied to the substrate 602 during the cooling process. The upper warpage control assembly 636 and the lower warpage control assembly 638 are also configured to provide rapid heat transfer from the substrate 602 in order to cool the substrate 602. After the cooling process, the lower warpage control assembly 638 is lowered and the lift pins 626 raise the substrate 602 off of the upper surface 648 of the lower warpage control assembly 638 as illustrated in view 800D of FIG. 8D. The substrate 602 is then removed from the cooling station 606 for subsequent processing.

FIG. 7 is a top down view of an apparatus 700 for reducing warpage of a substrate in accordance with some embodiments. The substrate is not shown to allow for illustration of further details of a transferable pedestal 716. The apparatus 700 includes a heating station 704, a transfer duct 708, a cooling station 706, and the transferable pedestal 716. The transferable pedestal 716 has several slots 722 that allow for clearance of lift pins 726 of a lower warpage control assembly 730. The slots 722 allow the lift pins 726 to raise and lift the substrate from transferable pedestal 716 and to allow the transferable pedestal 716 to retreat 728 while the substrate remains on top of the lift pins 726. The slots 722 also function as openings for direct temperature readings of a bottom surface of the substrate by heat sensors 732 positioned on a heat sensor assembly 736. In some embodiments, an additional optional heat sensor 734 may be positioned on the heat sensor assembly 736 to read temperatures of the bottom surface of the substrate not covered by the other heat sensors 732. An optional opening 718 may be incorporated into the transferable pedestal 716 to allow direct temperature readings by the optional heat sensor 734. In some embodiments, the transferable pedestal 716 has a projection 714 that interacts with a rod 712 from driven by an actuator 710. In some embodiments, the projection 714 may include an insulated portion 738 that prevents the transferable pedestal 716 from heating the rod 712 and actuator 710. The actuator 710 is in communication with the system controller (608 of FIG. 6) to control the movement 720 of the transferable pedestal 716 between the heating station 704 and the cooling station 706. The transfer duct 708 provides an insulative buffer between the heating station 704 and the cooling station 706.

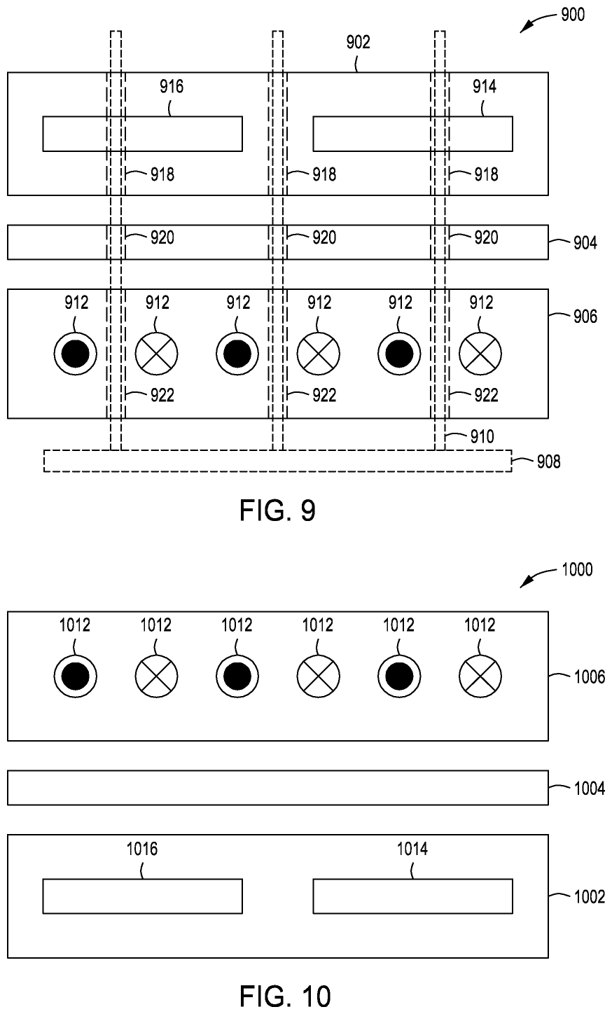

FIG. 9 is a cross-sectional view of a lower warpage control assembly 900 in accordance with some embodiments. The lower warpage control assembly 900 includes a lower electrostatic chuck assembly 902 that is configured to apply an electrostatic field into a substrate positioned above the lower electrostatic chuck assembly 902. In some embodiments, the electrostatic chuck assembly 902 may provide an electrostatic field with a positive or negative voltage of approximately 500 volts to approximately 2000 volts. In some embodiments, the electrostatic chuck assembly 902 may provide an electrostatic field with a positive or negative voltage of approximately 1000 volts. In some embodiments, the lower electrostatic chuck assembly 902 is formed of an aluminum nitride material with at least two lower electrodes 914, 916 that are configured to provide the electrostatic field into the substrate. The lower electrodes 914, 916 may have opposite polarities. The lower electrostatic chuck assembly 902 may be in communication with the system controller 608 to control the lower electrostatic field. The lower electrostatic chuck assembly 902 and lower electrodes have openings 918 to allow lift pins 910 (attached to a lift pin support 908) to pass through the lower electrostatic chuck assembly 902. The lower warpage control assembly 900 also includes a lower liquid convection cooling assembly 906 that is configured to rapidly cool a bottom surface of the substrate. In some embodiments, the lower liquid convection cooling assembly 906 is formed of an aluminum material with vacuum brazed cooling channels 912. The vacuum brazing allows the cooling channels to be formed without using copper liners, increasing thermal conductivity. The lower liquid convection cooling assembly 906 has openings 922 to allow lift pins 910 to pass through the lower liquid convection cooling assembly 906. In some embodiments, the lower electrostatic chuck assembly 902 is affixed to the lower liquid convection cooling assembly 906 with a lower thermal transfer tape 904 with openings 920 for allowing the lift pins 910 to pass through. In some embodiments, the lower thermal transfer tape has a transfer conductivity of approximately 0.5 W/mK to approximately 1.0 W/mK.

FIG. 10 is a cross-sectional view of an upper warpage control assembly 1000 in accordance with some embodiments. The upper warpage control assembly 1000 includes an upper electrostatic chuck assembly 1002 that is configured to apply an electrostatic field into a substrate positioned below the upper electrostatic chuck assembly 1002. In some embodiments, the upper electrostatic chuck assembly 1002 may provide an electrostatic field with a positive or negative voltage of approximately 500 volts to approximately 2000 volts. In some embodiments, the upper electrostatic chuck assembly 1002 may provide an electrostatic field with a positive or negative voltage of approximately 1000 volts. In some embodiments, the upper electrostatic chuck assembly 1002 is formed of an aluminum nitride material with at least two upper electrodes 1014, 1016 that are configured to provide the electrostatic field into the substrate. The upper electrodes 1014, 1016 may have opposite polarities. The upper electrostatic chuck assembly 1002 may be in communication with the system controller 608 to control the upper electrostatic field. The upper warpage control assembly 1000 also includes an upper liquid convection cooling assembly 1006 that is configured to rapidly cool a top surface of the substrate. In some embodiments, the upper liquid convection cooling assembly 1006 is formed of an aluminum material with vacuum brazed cooling channels 1012. The vacuum brazing allows the cooling channels to be formed without using copper liners, increasing thermal conductivity. In some embodiments, the upper electrostatic chuck assembly 1002 is affixed to the upper liquid convection cooling assembly 1006 with an upper thermal transfer tape 1004. In some embodiments, the upper thermal transfer tape has a transfer conductivity of approximately 0.5 W/mK to approximately 1.0 W/mK.

The cooling rates of the lower warpage control assembly 900 and the upper warpage control assembly 1000 may controlled in unison or independent of each by the system controller 608. Similarly, the electrostatic fields of the lower warpage control assembly 900 and the upper warpage control assembly 1000 may controlled in unison or independent of each other by the system controller 608. The independent control of the cooling rates and/or the electrostatic fields along with adjustments in the clamping forces allows for fine tuning of the warpage control process.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for reducing warpage of a substrate, comprising:
heating the substrate with an epoxy layer to at least a glass transition temperature of the epoxy layer while allowing the substrate to expand;
constraining the substrate with a clamping force exerted towards the substrate from a top direction and a bottom direction;
applying at least one electrostatic field to the substrate; and
rapidly cooling the substrate.

2. The method of claim 1, further comprising:
maintaining the at least the glass transition temperature of the substrate until the substrate is constrained.

3. The method of claim 1, further comprising:
constraining the substrate with a clamping force of approximately 5000N to approximately 7000N.

4. The method of claim 1, further comprising:
generating the electrostatic field with a first electrostatic chuck positioned above the substrate and a second electrostatic chuck positioned below the substrate.

5. The method of claim 1, further comprising:
using at least one liquid convection heat sink to rapidly quench cool the substrate at a rate of approximately 1300 W/m²° C. to approximately 3100 W/m²° C. to retain an elongated and low stress state of the epoxy layer.

6. The method of claim 5, further comprising:
using a first liquid convection heat sink positioned above the substrate and a second liquid convection heat sink positioned below the substrate.

7. The method of claim 1, further comprising:
generating at least one electrostatic field with at least one electrostatic chuck with two embedded half-moon electrodes.

8. The method of claim 1, further comprising:
heating the substrate to a glass transition temperature of approximately 100 degrees Celsius to approximately 200 degrees Celsius.

9. The method of claim 1, further comprising:
applying at least one electrostatic field with a positive or negative voltage of approximately 500 volts to approximately 2000 volts.

10. The method of claim 1, further comprising:
heating the substrate with a gas at a temperature of approximately 200 degrees Celsius to approximately 300 degrees Celsius and a pressure of approximately 1 bar to approximately 2 bar.

11. The method of claim 1, further comprising:
concurrently constraining the substrate, cooling the substrate, and applying the electrostatic field to the substrate for approximately 30 seconds to approximately 300 seconds.

12. A non-transitory, computer readable medium having instructions stored thereon that, when executed, cause a method of reducing warpage of a substrate to be performed, the method comprising:
heating the substrate with an epoxy layer to at least a glass transition temperature of the epoxy layer while allowing the substrate to expand;
maintaining the at least the glass transition temperature of the substrate until the substrate is constrained;
constraining the substrate with a total clamping force of approximately 5000N to approximately 7000N exerted towards the substrate from a top direction and a bottom direction;
applying at least one electrostatic field to the substrate with a first electrostatic chuck positioned above the substrate and a second electrostatic chuck positioned below the substrate; and
rapidly cooling the substrate using a first liquid convection heat sink positioned above the substrate and a second liquid convection heat sink positioned below the substrate.

13. The non-transitory, computer readable medium of claim 12, further comprising:
heating the substrate to a glass transition temperature of approximately 100 degrees Celsius to approximately 200 degrees Celsius.

14. The non-transitory, computer readable medium of claim 12, further comprising:
applying at least one electrostatic field with a voltage of approximately 500 volts to approximately 2000 volts.

15. The non-transitory, computer readable medium of claim 12, further comprising:
concurrently constraining the substrate, cooling the substrate, and applying the electrostatic field to the substrate for approximately 30 seconds to approximately 300 seconds.

16. An apparatus for reducing warpage of a substrate with an epoxy layer, comprising:
a first station with a gas heating system and a transferable pedestal that holds the substrate, wherein the first station is configured to heat the substrate to at least a glass transition temperature of the epoxy layer; and
a second station with a first warpage control assembly configured to receive the substrate from the first station, to provide a clamping force to a bottom surface of the substrate, to provide an electrostatic field to the substrate, and to provide cooling to the substrate, and a second warpage control assembly located above the first warpage control assembly configured to provide a clamping force to a top surface of the substrate, to provide an electrostatic field to the substrate, and to provide cooling to the substrate,
wherein the first station and the second station are configured to transfer the substrate between the first station and the second station with the transferable pedestal while maintaining the at least the glass transition temperature of the substrate.

17. The apparatus of claim 16, wherein the first warpage control assembly has a lift pin assembly for raising and lowering the substrate on and off of an upper surface of the first warpage control assembly.

18. The apparatus of claim 16, the first station further comprising:
a gas distribution assembly located at a top of the first station; and
a conduction heater assembly positioned under the transferable pedestal,
wherein the first station is configured to heat the substrate with a heated gas supplied by the gas distribution assembly from above the substrate and to heat the substrate with the conduction heater assembly from below the substrate.

19. The apparatus of claim 16, the first station further comprising:
infrared heat detectors located at a bottom of the first station and configured to detect a temperature of a bottom surface of the substrate, wherein the transferable pedestal has openings that permit direct readings from the bottom surface of the substrate by the infrared heat detectors.

20. The apparatus of claim 16, the second station further comprising:
an annular gas distribution assembly is positioned at a top of the second station and outward of the second warpage control assembly, wherein the annular gas distribution assembly is configured to surround the substrate with heated gas to maintain the at least the glass transition temperature of the substrate;
a first liquid convection cooling assembly configured to rapidly cool a bottom surface of the substrate, wherein the first liquid convection cooling assembly is formed of aluminum material with vacuum brazed cooling channels;
a second liquid convection cooling assembly configured to rapidly cool a top surface of the substrate concurrently with the first liquid convection cooling assembly, wherein the second liquid convection cooling assembly is formed of aluminum material with vacuum brazed cooling channels;
a first electrostatic chuck assembly configured to apply a first electrostatic field of approximately 500 volts to approximately 2000 volts below the substrate, wherein the first electrostatic chuck assembly is formed of aluminum nitride material with at least two electrodes configured to provide the first electrostatic field; and
a second electrostatic chuck assembly configured to apply a second electrostatic field of approximately 500 volts to approximately 2000 volts above the substrate concurrently with the first electrostatic chuck assembly, wherein the second electrostatic chuck assembly is formed of aluminum nitride material with at least two electrodes configured to provide the second electrostatic field,
wherein the first liquid convection cooling assembly is affixed to a lower surface of the first electrostatic chuck assembly with a first thermal transfer tape with a transfer conductivity of approximately 0.5 W/mK and approximately 1.0 W/mK,
wherein the second liquid convection cooling assembly is affixed to an upper surface of the second electrostatic chuck assembly with a second thermal transfer tape with a transfer conductivity of approximately 0.5 W/mK and approximately 1.0 W/mK, and
wherein the first warpage control assembly is configured to be raised and lowered and to provide a clamping force to the substrate by raising the substrate until the substrate is clamped between the first warpage control assembly and the second warpage control assembly.
